(19) United States
(12) Patent Application Publication
(10) Pub. No.: US 2023/0023819 A1
(43) Pub. Date: Jan. 26, 2023

(54) SYSTEMS AND METHODS FOR THERMAL MANAGEMENT AND PASSIVE COOLING OF LOCALIZAED HEAT FLUX ZONES

(71) Applicant: Phase Change Energy Solutions, Inc., Greensboro, NC (US)

(72) Inventors: Reyad I. Sawafta, Greensboro, NC (US); Rami M. Saeed, Greensboro, NC (US)

(73) Assignee: Phase Change Energy Solutions, Inc., Greensboro, NC (US)

(21) Appl. No.: 17/786,167

(22) PCT Filed: Dec. 16, 2020
(86) PCT No.: PCT/US2020/065274

§ 371 Date: Jun. 16, 2022

Related U.S. Application Data
(60) Provisional application No. 62/948,721, filed on Dec. 16, 2019.

(51) Int. Cl. H05K 7/20; H05K 5/02

(52) U.S. Cl. CPC H05K 7/20445; H05K 5/0213

(57) ABSTRACT

In one aspect, thermal management units are described herein which, in some embodiments, offer one or more advantages compared to other units for managing or controlling thermal energy. In particular, units and systems described herein incorporate one or more phase change materials (PCMs), such as one or more PCMs having a certain phase transition temperature, latent heat, and/or phase transition type. The PCMs are contained in equipment housing with the application of various components to provide management or controlling of thermal energy.

### CROSS-REFERENCE TO RELATED APPLICATIONS

The present patent application claims the benefit and priority of U.S. Provisional Patent Application No. 62/948,721, filed on Dec. 16, 2019, titled “SYSTEMS AND METHODS FOR THERMAL MANAGEMENT AND PASSIVE COOLING OF LOCALIZED HEAT FLUX ZONES,” the contents of which is hereby incorporated by reference in its entirety.

### FIELD

The present disclosure relates to thermal management systems or units including a phase change material (PCM) or latent heat storage material, and to methods of absorbing and releasing thermal energy using such systems or units.

### BACKGROUND

Telecommunications cable operators typically run fiber cables from a central location to cable access nodes placed in specific service areas, such as neighborhoods. A coaxial cable is then used to connect the nodes to or end users' or customers' premises. Such cable access nodes can present temperature or thermal energy management challenges due to the presence of heat-generating components (such as cables and other electronic components) within the nodes. Other containers, in addition to cable access nodes, can also present temperature control or thermal management challenges, including but not limited to in the electronics and telecommunications industries.

Temperature control can be even more difficult to achieve when the relevant containers or spaces are standardized. For example, a customized node enclosure is often needed for use with each of a number of different cable technologies due to the different physical, electrical and thermal specifications required by each. Temperature control of computer hardware cases or components (such as associated with central processing units (CPUs) and/or auxiliary devices such as keyboards) can also be difficult to achieve. Temperature control or thermal management of containers, compartments, or spaces can be especially challenging as the size of electronic components decreases, leading to an increase in the total number (and often, power consumption or heat generation) of electronic components per unit volume (e.g., per unit volume within a cable access node or electronics cabinet or other enclosure).

Some previous efforts to manage the temperature of electronic components or enclosures have used traditional cooling fins to dissipate heat. Unfortunately, standard cooling fins have a certain limit in terms of the rate of heat that can be removed. Further, mechanical cooling means increase costs through maintenance and electricity. Improved units, systems, and methods for thermal energy management and temperature control are therefore desired.

### SUMMARY

In one aspect, thermal management units are described herein which, in some embodiments, offer one or more advantages compared to other units for managing or controlling thermal energy. In particular, units and systems described herein incorporate one or more phase change materials (PCMs), such as one or more PCMs having a certain phase transition temperature, latent heat, and/or phase transition type. In addition, as described further below, it is believed that such units and systems provide improved systems and methods for managing the heat and temperature of telecommunications and electronic equipment and enclosures, such as generic access nodes, telecommunications equipment disposed in such nodes, and other heat-generating or temperature-sensitive equipment that are housed in other types of containers or enclosures. In some cases, a PCM described herein is combined with or disposed or dispersed in a matrix or interconnected network of metallic struts. In such instances, the PCM can act as a passive cooling source and can extend the effective reach (in distance) of the cooling source (or heat sink), or effectively bring the heat sink “closer” to the heat or heat flux or source of heat needing to be dissipated or cooled. As described further herein, the PCM, in some preferred embodiments, has a “freezing” point or temperature (or other “low end” phase transition point or temperature) that is high enough to passively charge under normal ambient conditions (for example, above 50° C.), and a “melting” point or temperature (or other “high end” phase transition point or temperature) that is low enough to prevent overheating in the equipment by absorbing heat (for example, below 80° C.).

Moreover, in some embodiments, a unit or method described herein can provide more heat dissipation in a manner that is capable of storing heat or thermal energy and releasing it to ambient at the same time. Further, in some cases, a unit described herein can be mounted on the surfaces of the bottom and lid of an enclosure or equipment housing. Such a unit described herein is used for managing excess heat or thermal energy from electronic or telecommunications equipment or other equipment, or for maintaining a desired temperature or operating temperature range for such equipment.

In one aspect, heat and temperature management units or systems are described herein. In some embodiments, a heat and temperature management unit described herein comprises one or more metallic sheets (which may define a housing) having an interior volume. Additionally, the housing can comprise a sub-housing. The sub-housing may also have an interior volume or space, and may be formed from one or more metallic sheets or other thermally conductive materials. The sub-housing can comprise or have disposed within it a thermally conductive matrix. For instance, in some cases, the thermally conductive matrix comprises a honeycomb matrix, a metallic foam structure, or any other interconnected network of metallic struts to facilitate conduction-based heat transfer between the interior volume and PCM. In some embodiments, the PCM component is disposed within the interior matrix or foam structure. In this manner, the sub-housing and its contents can together serve as a PCM-containing component. In some cases, the PCM-containing component comprises sides walls housing the interconnected network of metallic struts and one or more mounting structures, such as fastener, connecting the PCM-containing component to the exterior housing unit.

In some cases, depending on the Pores Per Inch (PPI) and relative density needed, the interconnected network of metallic struts of the PCM-containing component can comprise or be formed from one or more thermally conductive materials. Any material operable to facilitate heat transfer from the computing equipment to the PCM can be used. Some non-limiting examples of materials include a thermally conductive metal or mixture or alloy of metals (such as aluminum or copper. A composite material may also be used. In some cases, a thermally conductive component described herein is formed from carbon (e.g., carbon fiber, such as carbon fiber coated with boron nitride and copper particles) or silicon carbide (SiC). In some cases, 2-30% of relative density (relative to an identical non-porous alloy) is desired. Additionally, in some embodiments, a number of 5-100 PPI is used.

The equipment housing can be for cable access node, temperature-sensitive unit, telecommunication equipment, computing-related equipment, mechanical equipment, electrical equipment, or any equipment with a localized heat flux zone. Thus, in some embodiments, the system described herein can be used to manage heat or control temperature in automobiles, batteries, electronics, munitions, or computing context.

The PCM-containing component, in some cases, is designed to maintain a specific desired temperature (as described further below) inside the equipment housing. This temperature can be based on the phase transition temperature of the PCM used in the unit. In some embodiments, the metallic sheet structure serves as a housing structure for the PCM component and the interior honeycomb or foam structure. The honeycomb or foam structure can operate to conduct heat and facilitate heat transfer between the computing (or other heat-generating) equipment and the interior volume (PCM component), and from the PCM component to the ambient outside and the external environment. Any amount of PCM not inconsistent with the objectives of the present disclosure may be used. In some cases, for example, 1-3 lbs. of PCM per PCM-containing component (metallic sheet structure or sub-housing) is desired. Moreover, a number of (e.g., 1-20) PCM-containing components (metallic sheet structure or sub-housing and other interior components) may be needed depending on the size of the equipment housing.

In some cases, depending on the density and shape of the honeycomb or metallic foam or other thermally conductive material, at least 50% of the interior volume of the thermally conductive material is occupied by the PCM. In other embodiments, a range of 50% or greater of the interior volume of the thermally conductive material is occupied by the PCM. It is known that certain applications may operate with lower than 50% of the interior volume consisting of PCM, however, such applications are based upon goals of temperature control and are consistent with the disclosure herein.

Any PCM not inconsistent with the objectives of the present disclosure can be used. In some cases, for instance, a PCM comprises one or more of the following a salt hydrate; a fatty acid (e.g., having a C4 to C28 aliphatic hydrocarbon tail, which can be saturated or unsaturated, linear or branched, where a chemical species described as a “Cn” species (e.g., a “C4” species or a “C28” species) is a species of the identified type that includes exactly “n” carbon atoms; thus, a C4 to C28 aliphatic hydrocarbon tail refers to a hydrocarbon tail that includes between 4 and 28 carbon atoms); an alkyl ester of a fatty acid (such as a C2 to C6 ester alkyl backbone or a C6 to C12 ester alkyl backbone or a C12 to C28 ester alkyl backbone); a fatty alcohol (such as a fatty alcohol having a C4 to C28 aliphatic hydrocarbon tail); a fatty carbonate ester, sulfonate, or phosphonate (such as a C4 to C28 alkyl carbonate ester, sulfonate, or phosphonate); a paraffin; a polymeric material (such as a polymeric material). In some cases, the PCM is a PCM solder under the trade name BioPCM®, available from Phase Change Energy Solutions (Asheboro, N.C.), such as BioPCM-(−8), BioPCM-(−6), BioPCM-(−4), BioPCM-(−2), BioPCM-4, BioPCM-6, BioPCM 08, BioPCM-Q12, BioPCM-Q15, BioPCM-Q18, BioPCM-Q20, BioPCM-Q21, BioPCM-Q23, BioPCM-Q25, BioPCM-Q27, BioPCM-Q30, BioPCM-Q32, BioPCM-Q35, BioPCM-Q37, BioPCM-Q42, BioPCM-Q49, BioPCM-55, BioPCM-60, BioPCM-62, BioPCM-65, BioPCM-69, and others.

It is further to be understood that a PCM described herein can comprise a plurality of differing PCMs, including differing PCMs of differing types. Any mixture or combination of differing PCMs not inconsistent with the objectives of the present disclosure may be used. In some embodiments, for example, a thermal energy management unit or system comprises one or more fatty acids and one or more fatty alcohols. Further, as described above, a plurality of differing PCMs, in some cases, is selected based on a desired phase transition temperature and/or latent heat of the mixture of PCMs.

Further, in some embodiments, one or more properties of a PCM described herein can be modified by the inclusion of one or more additives. Such an additive described herein can be mixed with a PCM and/or disposed in a unit described herein. In some embodiments, an additive comprises a thermal conductivity modulator. A thermal conductivity modulator, in some embodiments, increases the thermal conductivity of the PCM. In some embodiments, a thermal conductivity modulator comprises carbon, including graphitic carbon. In some embodiments, a thermal conductivity modulator comprises carbon black and/or carbon nanoparticles. Carbon nanoparticles, in some embodiments, comprise carbon nanotubes and/or fullerenes. In some embodiments, a thermal conductivity modulator comprises a graphitic matrix structure. In other embodiments, a thermal conductivity modulator comprises an ionic liquid. In some embodiments, a thermal conductivity modulator comprises a metal, including a pure metal or a combination, mixture, or alloy of metals. Any metal not inconsistent with the objectives of the present disclosure may be used. In some embodiments, a metal comprises a transition metal, such as silver or copper. In some embodiments, a metal comprises an element from Group 13 or Group 14 of the periodic table. In some embodiments, a metal comprises aluminum, or aluminum alloys such as 1050A, 6060, 6063. Additionally, composite materials may be used such as copper-tungsten pseudo alloy, silicon carbide in an aluminum matrix, diamond in copper silver alloy matrix, and e-material such as beryllium oxide in beryllium matrix. In some embodiments, a thermal conductivity modulator comprises a metallic filler dispersed within a matrix formed by the PCM. In some embodiments, a thermal conductivity modulator comprises a metal matrix structure or cage-like structure, a metal tube, a metal plate, and/or metal shavings. Further, in some embodiments, a thermal conductivity modulator comprises a metal oxide. Any metal oxide not inconsistent with the objectives of the present disclosure may be used. In some embodiments, a metal oxide comprises a transition metal oxide. In some embodiments, a metal oxide comprises alumina.

In other embodiments, an additive comprises a nucleating agent. A nucleating agent has a surface charge that is opposite to the partial charge of the chemical moiety of the polymer. Nucleating agents accelerate the rate of crystallization, and a melting point that is greater than the melting point of the melt processible polymer. A nucleating agent, in some embodiments, can help avoid subcooling, particularly for PCMs comprising finely distributed phases, such as fatty alcohols, paraffinic alcohols, amines, and paraffins. Any nucleating agent not inconsistent with the objectives of the present disclosure may be used.

Additionally, in some embodiments, the PCM component changes phase from a first phase to a second phase by exposing the phase change material to an ambient temperature below a phase change (or transition) temperature of the phase change material. Further, in a method or unit or system described herein includes reverting the phase change material to the first phase due to the heat produced by the computing (or other heat-generating) equipment inside the equipment housing. During this process, the temperature of the computing equipment can be maintained at or below the PCM temperature. Further, this process is not only applicable to computing but includes all types of mechanical and electrical equipment in which the controlling of operating temperatures and parameters is required.

It should further be noted that the various components of systems and units described herein (for example, the PCM-containing components, including sub-housings and thermally conductive matrices, and PCMs) can have any physical dimensions not inconsistent with the objectives of the present disclosure. For example, in some cases, the PCM-containing component (including a sub-housing, a thermally conductive matrix disposed in the sub-housing, and a PCM disposed in the matrix) is a relatively thin or sheet-like component, when compared to the dimensions of the equipment housing in which it is disposed.

These and other implementations are described in more detail in the drawings and detailed description which follows.

### BRIEF DESCRIPTION OF THE DRAWINGS

Many aspects of the present disclosure will be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views. It should be recognized that these implementations and embodiments are merely illustrative of the principles of the present disclosure.

FIG. 1 sets forth a top and bottom perspective of an example embodiment of equipment housing for a thermal management unit, the equipment housing consists of a bottom interior volume and a lid that closes via a mounting structure, a top view of the bottom side of housing and a top view of the lid are provided.

FIG. 2 sets forth an isometric perspective view of an example embodiment of equipment housing for a thermal management unit.

FIG. 3 sets forth an isometric perspective view of an example embodiment of equipment housing for a thermal management unit, a view of the bottom housing and lid are provided.

FIG. 4 sets forth a perspective view of an example embodiment of equipment housing for a thermal management unit, a view of the bottom and top interior housing is provided.

FIG. 5 sets forth an isometric perspective view of an example embodiment of equipment housing for a thermal management unit, a view of the bottom and top interior housing is provided.

FIG. 6 sets forth a perspective view of an example embodiment of an assembled equipment housing for a thermal management unit.

FIG. 7 sets forth a perspective view of an example embodiment of equipment housing for a thermal management unit with a honeycomb matrix.

FIG. 8 sets for a perspective view of an example embodiment of equipment housing for a thermal management unit with a metallic foam structure.

FIG. 9 sets forth a perspective view of an example embodiment of equipment housing for a thermal management unit with metallic fins disposed on the exterior.

FIG. 10 sets forth a perspective of an example embodiment of equipment housing for a thermal management unit with metallic fins disposed in the interior volume of the equipment housing.

FIG. 11 sets forth a perspective view of an example embodiment of a thermal management unit with an equipment housing, and subunit equipment housing.

FIG. 12 sets forth a perspective view of an example embodiment of a thermal management unit mounted to a heat generating component.

FIG. 13 sets forth a perspective view with a cut away of an example embodiment of a thermal management unit with a liquid state PCM material in the interior volume.

FIG. 14 sets forth a perspective view with a cut away of an example embodiment of a thermal management unit with a solid state PCM material in the interior volume.

FIG. 15 sets forth a flow diagram of an example embodiment of a thermal management unit.

### DETAILED DESCRIPTION

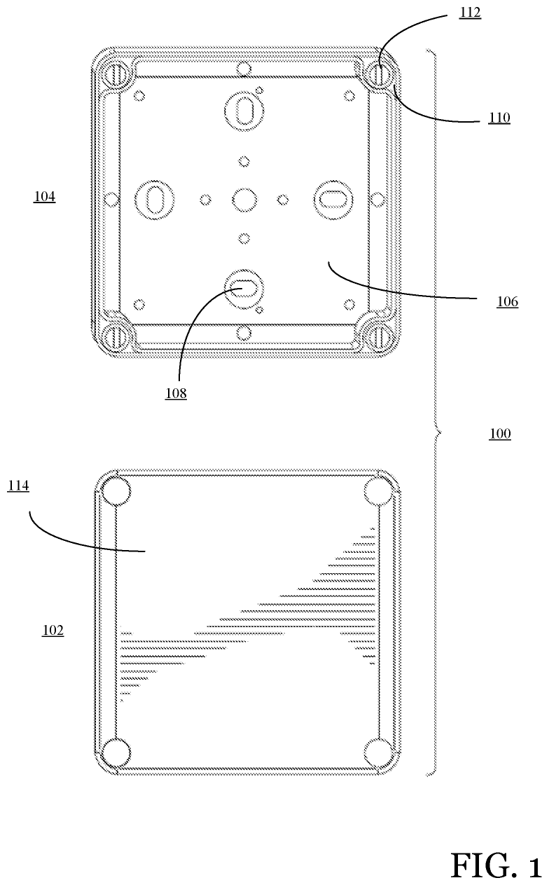

Implementations and embodiments described herein can be understood more readily by reference to the following detailed description, example embodiments, and drawings. In the following discussion, a general description of the system and its components and apparatuses is provided, along with a discussion of the methods and operations of the same. It will be known to those of skill in the art that multiple configurations of the equipment housing may be applied to achieve the results of the thermal management unit, and that the embodiments disclosed herein are but a few examples of preferred configurations and methods for using the same. We continue our discussion with the example embodiment of a thermal management unit according to FIG. 1.

In FIG. 1, an example embodiment of a top and bottom perspective of equipment housing for a thermal management unit is disclosed. The top portion (102) can be comprised of any material capable of withstanding temperature fluctuations and maintaining integrity with PCM and electrical and mechanical components. The top portion (102) and the bottom portion (104) are secured through the securing points (110) to form the equipment housing (100). It is important to note the equipment housing (100) will often take the shape, both in dimensions and in configuration, of the particular heat generating component.

The nature of PCM, and the applications thereof, allows for a variety of configurations and is an improvement over the prior art of metallic fins and heat exchangers. It is important to note, and reiterate, that any PCM not inconsistent with the objectives of the present disclosure can be used. As a synopsis, PCM is a substance which can release or absorb sufficient energy at a phase transition to provide useful heating and cooling properties, typically, by either melting and solidifying at a phase change temperature. The phase change transition may also include non-classical states of matter, such as forming a crystalline structure. There are several classes of PCM that are applicable to the present disclosure; organic, or carbon containing materials, derived from petroleum, plants, or animals; inorganic, namely salt hydrates; and eutectic, a mixture of both organic and inorganic components.

The PCM (or combination of PCMs) used in a particular instance can be selected based on a relevant operational temperature range for the specific end use or application. As understood by one having ordinary skill in the art, a phase transition temperature described herein (such as a phase transition temperature of “X” ° C., where X may be 50° C., for example) may be represented as a normal distribution of temperatures centered on X° C. In addition, as understood by one having ordinary skill in the art, a PCM described herein can exhibit thermal hysteresis, such that the PCM exhibits a phase change temperature difference between the “forward” phase change and the “reverse” phase change (e.g., a solidification temperature that is different from the melting temperature). For example, in some cases, the PCM has a phase transition temperature within a range suitable for heating or cooling a telecommunications node. In other instance, the PCM has a phase transition temperature suitable for the thermal energy management of so-called waste heat. In some embodiments, the PCM has a phase transition temperature within one of the ranges of Table 1 below.

TABLE 1
Phase transition temperature ranges for PCMs.
Phase Transition Temperature Ranges
70-100° C.
50-80° C.
45-85° C.
16-23° C.
16-18° C.
15-20° C.

As described further herein, a particular range can be selected based on the desired application. A PCM of a thermal energy storage system described herein can either absorb or release energy using any phase transition not inconsistent with the objectives of the present disclosure. For example, the phase transition of a PCM described herein, in some embodiments, comprises a transition between a solid phase and a liquid phase of the PCM, or between a solid phase and a mesophase of the PCM. A mesophase, in some cases, is a gel phase. Thus, in some instances, a PCM undergoes a solid-to-gel transition. Further, other transitions are known and disclosed herein, such as a solid to solid, solid to crystalline, a solid to liquid, liquid to crystalline, and a liquid to liquid change, to name a few.

Moreover, in some cases, a PCM or mixture of PCMs has a phase transition enthalpy of at least about 50 kJ/kg or at least about 100 kJ/kg. In other embodiments, a PCM or mixture of PCMs has a phase transition enthalpy of at least about 150 kJ/kg, at least about 200 kJ/kg, at least about 300 kJ/kg, or at least about 350 kJ/kg. In some instances, a PCM or mixture of PCMs has a phase transition enthalpy between about 50 kJ/kg and about 350 kJ/kg, between about 100 kJ/kg and about 350 kJ/kg, between about 100 kJ/kg and about 220 kJ/kg, or between about 100 kJ/kg and about 250 kJ/kg. Several distinct advantages of PCM for cooling based applications include the thermal control ability, the high latent heat storage capacity, the small volume change in phase transformation, the high specific heat capacity, the chemical stability and lack of degradation over many cycles, the high thermal conductivity, the high density of the material, the noncorrosiveness, the nonflammable aspects, the nontoxicity, and the relatively low cost of the material.

Returning to FIG. 1, the PCM is contained within the equipment housing (100) and held together with a fastener (112). The fastener (112) is often a screw or pin, but can form any type of fastener that can secure to a securing point, also referred to as a screw boss or fastener point. Often times a gasket or seal is placed between the top portion (102) and the bottom portion (104) to secure the contents of the bottom interior volume (106). The bottom interior volume (106) is scaled to meet the needs of temperature regulation and houses the PCM material along with additional disclosures as mentioned previously of a honeycomb matrix, a metallic foam, metallic fins, or other materials that can transfer heat and dissipate it accordingly. The top portion (102) may also contain an interior volume, and in additional embodiments, the interior volumes are complimentary, further, the top portion (102) may consist of a top surface (114) that is flush and nonobtrusive for applying to electrical equipment.

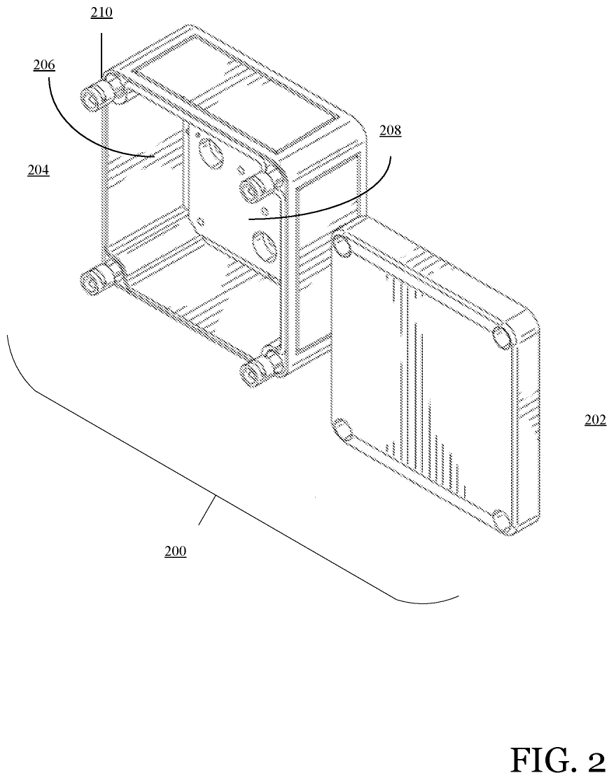

Turning to the example embodiment disclosed in FIG. 2. FIG. 2 sets forth an example embodiment of an isometric perspective view of equipment housing (200) for a thermal management unit. The equipment housing (200) comprises the top portion (202) and the bottom portion (204). The bottom interior volume (206) is readily apparent and the mounting structure (208) is depicted as well. Any mounting structure, capable of securing the equipment housing (100) to a heat generating component may be used. The present mounting structure, in FIG. 2, consists of several securing points and allows for secure applications including industrial and military hardware applications, as well as commercial and utility use applications. Further, the bottom portion (204) with the configured mounting structure (208) may be further configured with gaskets, or other material, to the heat generating component (not pictured). A gasket or seal is often used in applications where the heat generating component produces vibrations in which can cause stress on accompanying structures. Additionally, the mounting structure (208) is equipped to receive a variety of standards of mechanical fasteners, including metric, and imperial fasteners. Typically, the fasteners are used to create non-permanent joints, or joints that can be removed, dismantled, without damaging components. Permanent fasteners are also disclosed; such fasteners may be used on applications with long lifecycles in which PCM is equipped to handle. The fasteners (210) are configured to secure the top portion (202) with the bottom portion (204) to maintain the contents, including the PCM material within the equipment housing (200). It is also important to note that in additional embodiments the two portions of equipment housing may be crimped, welded, brazed, taped, glued, cemented, or otherwise affixed. Additionally, the equipment housing may be fabricated out of a solid piece of construction, with a plug or outlet in which to administer PCM. In a solid piece construction, the rigidity may allow for thinner edges and bezels to increase the volume and capacity of PCM.

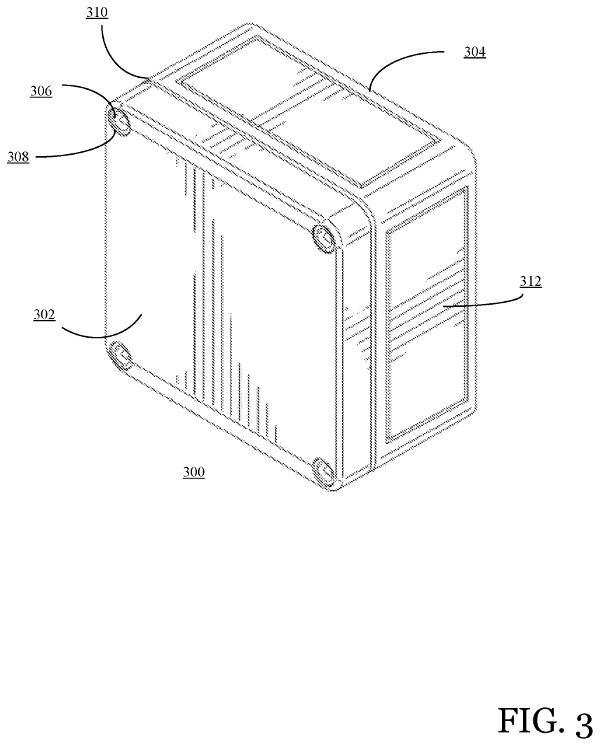

Turning now to FIG. 3. FIG. 3 is an example embodiment of an isometric perspective view of equipment housing with the top portion (302) and bottom portion (304) affixed by fasteners (306) to the securing points (308). The securing point (308) may also be known as a screw boss, or other type of receiving point, in which a fastener, either permanent or temporary, can be affixed to and provide the rigidity and strength to hold the top portion (302) to the bottom portion (304). Returning to the equipment housing (300) of the thermal management unit, in the example embodiment, a metal housing is utilized due to the physical properties of heat transfer, typically referred to as thermal conductivity. The thermal conductivity is defined as the amount of heat passing in unit time through a surface, in a direction that is normal to the surface. In general, a metallic structure is disclosed due to the high thermal conductivity, the malleable and ductile properties, and resistance to deformation under stress. However, additional equipment housing compositions are possible and may prove effective for particular cooling and or temperature management. For example, a carbon fiber equipment housing for a thermal management unit may be beneficial for apparatuses that require reduced weight and strong rigid structural integrity, or for apparatuses that face severe inclement weather or environmental conditions in which typical metals may degrade. In addition, polymer based equipment housing may be formed for lower cost and resistance to impact forces. Further, polymers have varying advantages and disadvantages over metal structures, but nonetheless comprise an efficient and effective equipment housing for additional embodiments of the present disclosure. Additionally, in some instances, a thermal conductivity of the housing is at least one order of magnitude higher than a thermal conductivity of a PCM used therewith, such as at least two orders of magnitude higher, or at least three orders of magnitude higher.

FIG. 3 discloses an interchangeable panel (312) in which additional embodiments may attach such as an additional thermal management unit. In such a fashion plug and play thermal management units may be combined based upon load or seasonality, forming a modular system that can grow and expand to meet thermal management control needs. The equipment housing (300) is also adaptable through the interchangeable panel (312) to add additional embodiments such as cooling fins (pictured later) or other apparatus that may aid in controlling temperature, such as digital thermometers, and thermos-wells. Further, in the example embodiment of FIG. 3 a gasket (310) is utilized to seal the top portion (302) to the bottom portion (304) of the equipment housing (300). Gaskets can range in shape and size and the material selected corresponds to the conditions of temperature gradient and the specific PCM. Gaskets and seals are often made of polymers that have little to nor activity to the constituents.

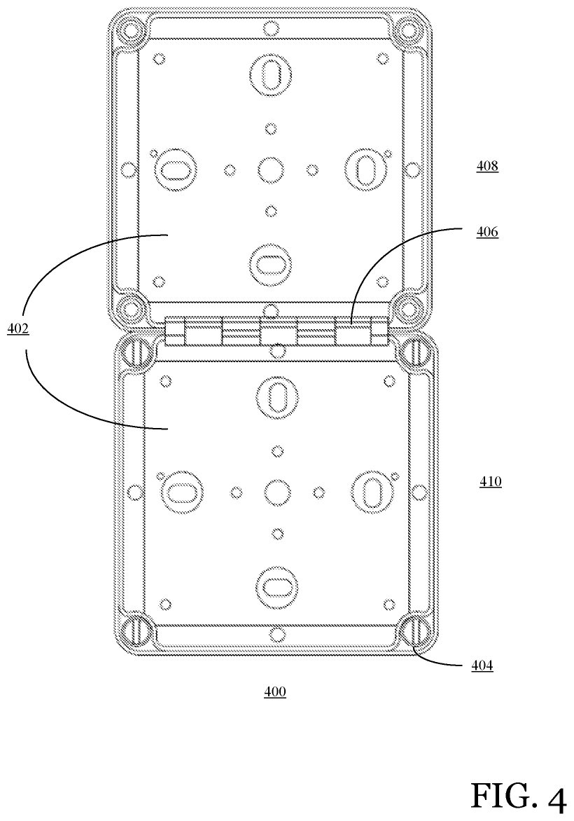

FIG. 4 sets forth an example embodiment of an equipment housing (400) for a thermal management unit. The mounting structure (402) is equipped on both the top and bottom surfaces in this example embodiment. By equipping mounting structures (402) the equipment housing may be placed in between two heat generating components, or stacked on top of additional thermal management units to form a series of thermal management units for additional temperature regulating capacity. The mounting structure (402) may form any number of compositions, including the ability to mount a honeycomb matrix on the interior volume, which providing stability and support on the exterior surface of the equipment housing to securely mount or affix to a heat generating component. In additional embodiments the mounting structure (402) provides a window with direct access to the heat generating component, in even further embodiments a conductive matrix is exposed to the heat generating component and has access to the interior volume of the equipment housing through the mounting structure. It is important to note the mounting structure (402) not only secures the equipment housing to a heat generating component but may also serve as a window for access to the heat generating component and the PCM. In this regard there may be a gasket surrounding the mounting structure in which to contain the PCM as the equipment housing is mounted to the heat generating component.

In FIG. 4 the top portion (408) and the bottom portion (410) are held together with a hinge (406). Often times the hinge may be referred to as a coupling member, and it is used interchangeably herein. In the present embodiment the hinge or coupling member serves to securely connect the top portion (408) with the bottom portion (410) and to contain the PCM. The hinge (408) or coupling member may also serve to hold the equipment housing in open configuration or to reverse the configuration. The open face configuration may then be placed or adhered through thermal paste or a mounting structure to the heat generating component. The hinge is fabricated to hold and contain PCM, but may also be designed to operate the equipment housing in open or closed form. In additional embodiments the hinge compresses a gasket or seal in which to hold the contents of the interior volume of the equipment housing (400). In further embodiments the hinge is replaced with a strap hinge that pushes the equipment housing onto a heat generating component. The strap hinge may be mounted to the heat generating component and only the top portion or bottom portion secured with the hinge against the heat generating component. In further embodiments the hinge is spring loaded for increasing pressure on the top portion and bottom portion for ease of securing the fasteners to the securing points (404). The securing points (404), as discussed previously, provide a location for fasteners to secure the contents of the interior volume of the top portion and bottom portion.

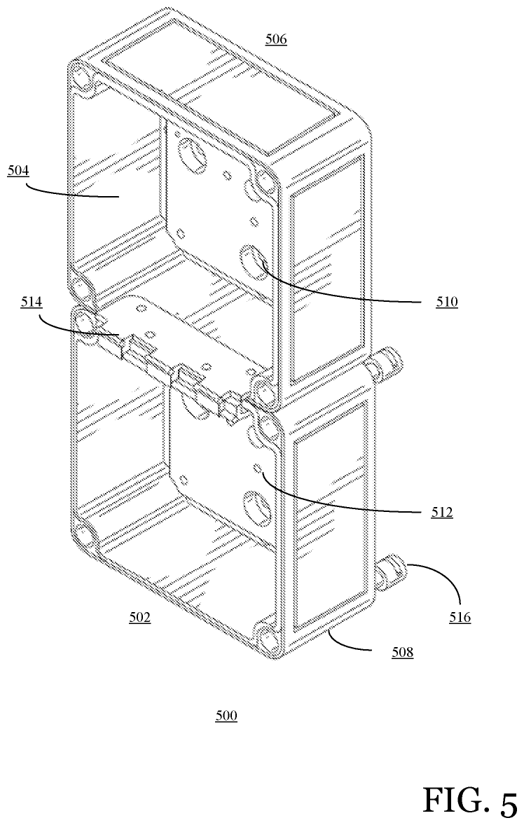

Turning now to FIG. 5. FIG. 5 sets forth an isometric view of an example embodiment of equipment housing (500) for a thermal management unit. In the example embodiment of FIG. 5 the bottom interior volume (502), and the top interior volume (504) is readily viewable. Inside either or both the bottom interior volume (502) and the top interior volume (504) may reside a metallic matrix, such as a honeycomb matrix or metallic foam matrix, or otherwise a metallic matrix in which it is connected through the various mounting structures to the heat generating component. The metallic matric components will be discussed later on in the detailed description, however, each component may apply to each and every embodiment applied. The metallic matrices allow for increased thermal conductivity and increased surface area with the PCM. Note, that thermal conductivity is defined as the

$$K = \frac{Qd}{A Δ T}$$

where K is thermal conductivity, Q is the amount of heat transfer, d is the distance between two isothermal planes, A is the area of the surface, and delta T is the change in difference in temperature. In some instances, a thermal conductivity of the metallic matrices is at least one order of magnitude higher than a thermal conductivity of the PCM, such as at least two orders of magnitude higher, or at least three orders of magnitude higher. Not intending to be bound by theory, a metal matrix formed from one or more materials which has a thermal conductivity one or more orders of magnitude higher than the PCM may facilitate heat absorption and/or dissipation by the PCM. The metallic matrix increases the area of the surface and the measureable benefits will be apparent to those of skill in the art.

In the example embodiment of FIG. 5, a hinge (514) is present to secure the top and bottom portions of the equipment housing (400) of the thermal management unit. The hinge (514) is constructed in the example embodiment to be completely interior to the equipment housing, thus creating a seal, and lacking visibility from the exterior of the equipment housing (400). Included is a top mounting structure (510) as well as a bottom mounting structure (512). The top portion and the bottom portion may operate as both bottom portions with two independent top portions secured on top, the embodiments of the equipment housing are depicted to show scalability and the plug and play nature of mounting and securing the various thermal management units. It is important to note the thermal management unit may be equipped with intelligence, by adding a microcontroller to the outside of the equipment housing, the microcontroller can be equipped to several sensors and probes, to actively take readings of the PCM or of the ambient environment and report through a wireless module the current conditions of the thermal management unit. Typical microcontrollers include systems equipped with RAM, long term storage, a processor, a I/O module or adapter, as well as a wireless or Bluetooth™ chipset for communications. By imparting computational intelligence, the thermal management unit can assist in relaying operating conditions and information to a central storage server or user, often times operating as a preventative measure of equipment malfunction.

The equipment housing (500) is secured by the fasteners (516) and in the example embodiment the fastener is a locking fastener that is capable of locking by twisting into place. The sides of the equipment housing (500) are capable of being equipped with additional structures and the previously discussed microcontroller may be mounted to the sides of the equipment housing with probes and sensors entering the side walls or through the mounting structure.

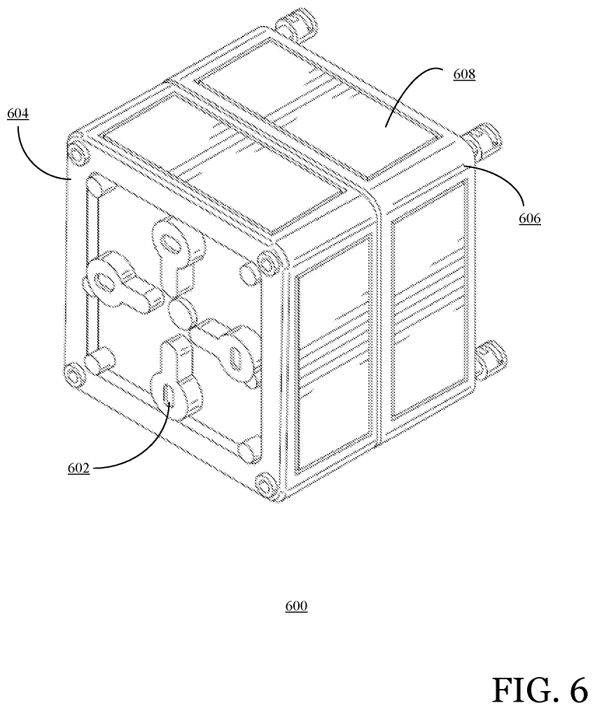

In the example embodiment of FIG. 6, an isometric view of equipment housing stacked on one another to form a thermal management unit is displayed. The top mounting structure (602) is equipped to mount additional thermal management units, the adaptive context of the equipment housing allows for additional temperature control for varying environments, it also allows for configurations of existing installations for seasonal adaptations or for handling varied cooling or temperature control conditions. For example, in the summer months a resource in an outdoor environment or close to the exterior of a building may require additional units, while in the winter months the additional units can be removed and supplied elsewhere, for instance near heating units or areas that may experience increased temperatures.

FIG. 6 displays the versatility of the equipment housing (600) and depicts a varying size and dimension to accommodate a variety of temperature control scenarios. The side panel (608) is both removable and serves as an attachment point for varying attachments as discussed previously. Similarly, in additional embodiments the side panel (608) is a permanent structure or is composed of a translucent material allowing viewing of the PCM.

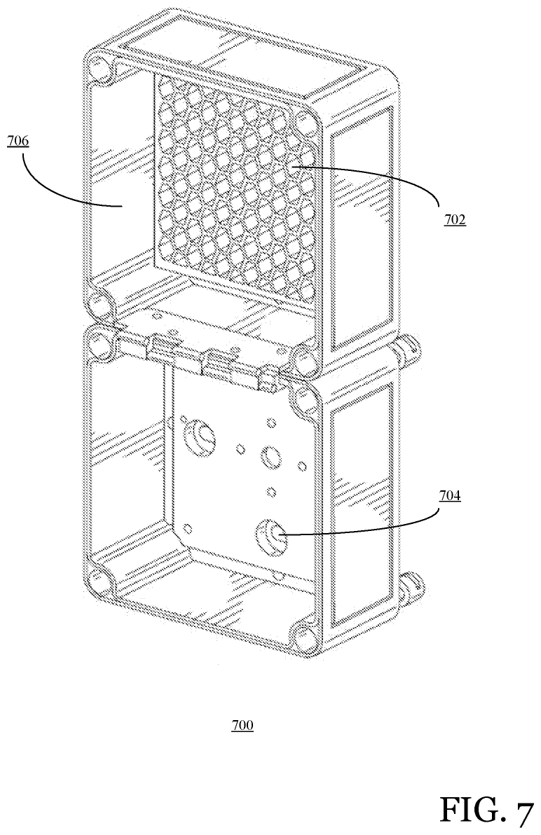

In FIG. 7, an example embodiment of an isometric view of equipment housing (700) for a thermal management unit, with the equipment housing equipped with a honeycomb matrix (702). The honeycomb matrix (702), also referred to as a thermally conductive matrix, in the example embodiment of FIG. 7, is configured with the mounting structure (not depicted) and increases the metallic surface area to the PCM in the interior volume (706) of the equipment housing (700). A few benefits of a honeycomb structure, and thermally conductive matrices in general, include the minimization of material to reach a minimal weight and material cost while also remaining rigid, and providing key properties of metals such as thermal conductivity. In the example embodiment a hollow cell honeycomb metallic matrix is used, in which the PCM material may enter the cells. In additional embodiments the honeycomb metallic matrix may occupy several rows of the interior volume (706), in doing so the surface area and contact with the PCM and the heat generating component is multiplicatively increased. In even further embodiments the honeycomb structure's hollow cells may be expanded or contracted to account for variability of the differing applications. The honeycomb structure allows for increased PCM contact and is useful in applications ranging from smaller equipment housing to large scale temperature control.

The metallic matrix may further lack the addition of Boron Nitride platelets, Boron Nitride cooling fillers are ceramic fillers that may improve thermal conductivity, these fillers are often utilized to dissipate heat. Other fillers may prove more beneficial than Boron Nitride, including compositions of silicon carbide, or other metals or alloys.

The mounting structure (704) as discussed previously, allows for differing configurations to account for a variety of applications, including mounting for extreme conditions. For example, the equipment housing and thermal management unit may be adapted to mount on the exterior of electrical or mechanical components that experience seasonal weather changes, shocks, impacts, and other conditions. The equipment housing for the thermal management unit is a versatile housing that may be certified dust and or water resistant to various standards, including Ingress Protection Codes, which is an IEC standard that classifies and rates the degree of protection provided by mechanical casings and electrical enclosures. Further, the mounting structure may be sealed with or in contact with thermal paste or other thermal conduit. Thermal paste, also known as thermal grease or thermal compound is a heat conductive compound that improves the conductivity, and is often used as a thermal interface material.

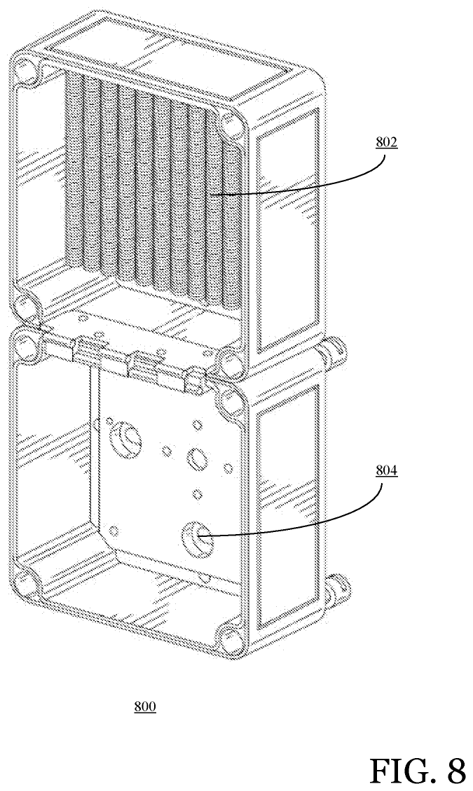

In FIG. 8, an example embodiment of an isometric view of equipment housing (800) for a thermal management unit, with the equipment housing equipped with a metallic foam structure (802). Metal foam is a cellular structure consisting of a solid metal, with gas filled pores comprising a large portion of the volume. Metal foams significantly increase surface area of the structure through the pores, which in turn allows the PCM material to occupy the pore space.

There are two main types of metal foams, open cell, also known as metal sponge, which has the pores exposed, and closed cell, which traps the pores. In the present embodiment a closed cell foam is used for its properties of increasing surface space. In additional embodiments a closed cell metallic foam may be used if, for instance, a floating metallic foam structure is desired within the equipment housing (800). Additionally, metal foams come in a variety of composites and metals. Some examples of additional embodiments include silicon carbide (SiC) foam and or metallic matrix, carbon fiber composite foam. Examples of silicon carbide foam include physical characteristics such as compression strength of 200 psi, flexural strength of 400 psi, shear strength of 100 psi, with bulk thermal conductivity at 250 degrees Celsius at 3.05 BTU/ft, and a high resistance to oxidation and corrosion. Silicon carbide is known for high thermal conductivity, due in part to the surface area of foam constructs, which further facilitate transfer to/from PCM flowing through the matrix.

SiC and SiC composites are mainly processed through three different methods. However, these processing methods are often subjected to variations in order to create the desired structure or property. First, the Chemical Vapor Infiltration (CVI) method which uses a gas phase SiC precursor to first grow SiC whiskers or nanowires in a preform, using conventional techniques developed with CVD. Following the growth of the fibers, the gas is again infiltrated into the preform to densify and create the matrix phase. Generally, the densification rate is slow during CVI, thus this process creates relatively high residual porosity (10-15%). The Polymer Impregnation and Pyrolysis (PIP) method, which uses preceramic polymers (polymeric SiC precursors) to infiltrate a fibrous preform to create a SiC matrix. This method yields low stoichiometry as well as crystallinity due to the polymer-to-ceramic conversion process. Additionally, reduction also occurs during this conversion process, resulting in 10-20% residual porosity. Multiple infiltrations can be performed to compensate for the shrinkage. Lastly, the Melt Infiltration (MI) method which has several variations, including using a dispersion of SiC particulate slurry to infiltrate into the fibrous preform, or using CVI to coat carbon on the SiC fibers, followed with infiltrating liquid Si to react with the carbon to form SiC. With these methods, chemical reactivity, melt viscosity, and wetting between the two components should be considered carefully. Some issues with infiltrating melted Si is that the free Si can lower the composite's resistance to oxidation and creep. However, this technique usually yields lower residual porosity (˜5%) compared to the other two techniques due to higher densification rates

The metal foams may also apply to stiffen the equipment housing, by occupying a large interior volume the metal foam may serve to bolster the equipment housing so that it may be load bearing or capable of handling increased loads or usage such as under electrical equipment of vehicles and machines or the like. The unique strength properties of metallic foams relative to weight allow for versatile applications that can control overall temperature regulation with weight limitations.

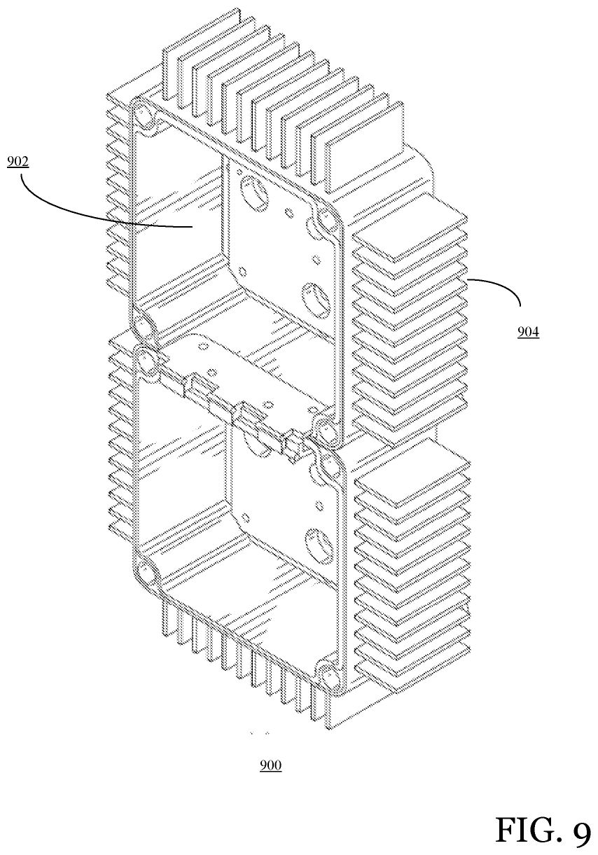

In FIG. 9, an example embodiment of an isometric view of equipment housing (900) for a thermal management unit is disclosed. On the exterior of the equipment housing (900) are sets of metallic fins (904), also commonly referred to as heat sinks, which increase the equipment housing's surface area to the environment. Metallic fins are often used in electrical components for passive thermoregulation. When the metallic fins (904) are used in connection with PCM, as set forth in the example embodiment, the thermal regulation capacity is improved. In additional embodiments the equipment housing and metallic fins are also aided by a fan, which moves air across the surface of the metallic fins and equipment housing. The embodiment of the metallic fins serves to increase the surface area with the cooling medium or environment surrounding them. Factors such as air velocity, choice of material, metallic fin protrusion design, and surface treatment are all factors that affect performance. Similar to the construction elements of the equipment housing, the metallic fins may be formed directly into the equipment housing or applied after manufacture for additional thermoregulation control to the surrounding environment.

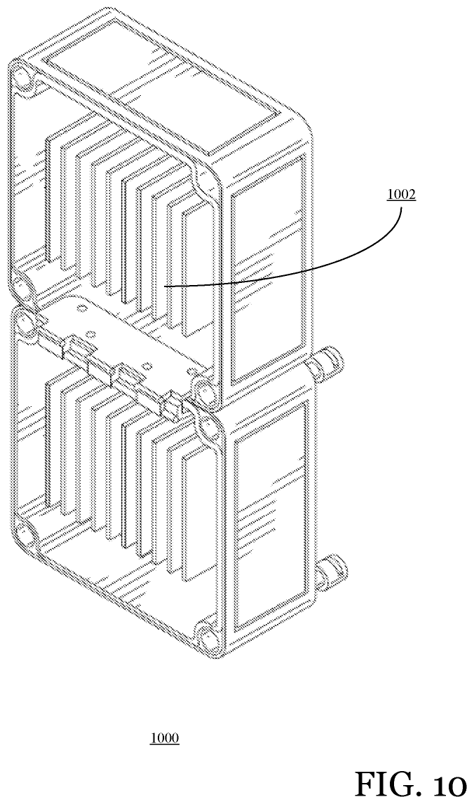

In FIG. 10, an example embodiment of isometric perspective view of equipment housing (1000) for a thermal management unit with metallic fins (1002), or a heat sink located in the internal volume of the equipment housing (1000). Similar to the honeycomb matrix, the metallic fins or heat sink internally increases the surface area contact with the PCM. Metallic fins share the same properties as the exterior metallic fins, and are often times composed of an aluminum or aluminum alloy, including aluminum alloy 1050A, or 6060, or 6063. With typical conductivity values ranging from 166 to 201 W/m*K. The metallic fins (1002), may be secured to the equipment housing through the mounting structure or assembled along the internal walls of the interior volume of the equipment housing. Similarly, the metallic fins may be used in combination with a metallic matrix to create additional thermoregulation and or to satisfy differing objectives. The relevant interior volume of PCM and metallic matrices is dependent upon the thermoregulation goals, and can vary with percentages of interior volume of PCM occupying 50% or greater.

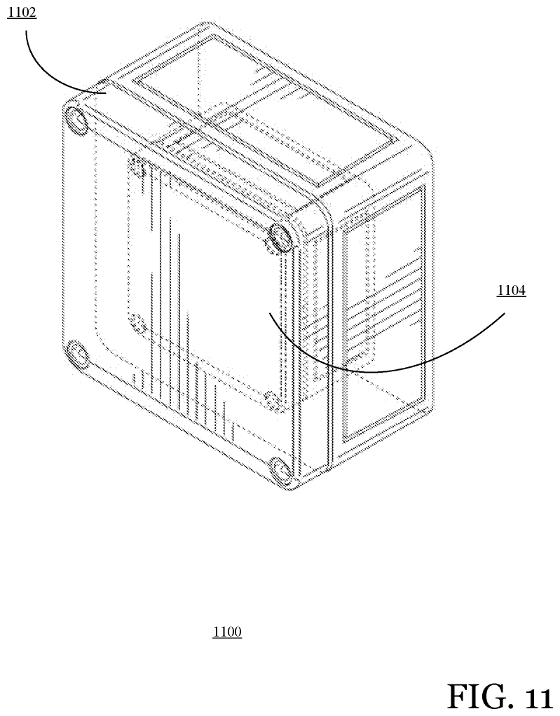

Turning now to FIG. 11. FIG. 11 is an example embodiment of a thermal management unit (1100) with equipment housing (1102) and subunit equipment housing (1104), or sub housing, containing PCM. In the example embodiment a nested set of equipment housing apparatus' are utilized to produce multiple levels of control. For example, the sub housing may contain PCM that is more reactive to a narrower temperature window, while the equipment housing containing it may contain PCM that covers a broader thermal range, and vice versa. The sub housing or subunit may be composed of the same composition as the equipment housing, including metals, alloys, compositions, polymers, and all other embodiments of equipment housing discussed herein. In the example embodiment the nested equipment housing forming the thermal management unit increases performance and control by adjusting the variables and utilizing several varieties of PCM. In this way a customized solution can be adapted by layering equipment housing and customizing the PCM for a given thermal controlling application.

The equipment housing (1102) may contain PCM that surrounds the subunit equipment housing (1104), forming a multi-stage thermal management unit. The benefits of subunits and additional equipment housing will be known to those of skill in the art. Turning now to the phase change material of a thermal energy storage system described herein, the PCM, in some preferred embodiments, is in direct physical contact with heat exchange surfaces of the heat generating component. In additional embodiments the conductive matrix is in direct contact with the heat exchange surface. For example, in some cases, as described above, the heat exchange surfaces are at least partially in contact, either through the equipment housing, or the mounting structure, or the conductive matrix with the PCM. Any PCM not inconsistent with the objectives of the present disclosure may be used in a thermal energy storage system described herein. Moreover, the PCM (or combination of PCMs) used in a particular instance can be selected based on a relevant operational temperature range for the specific end use or application

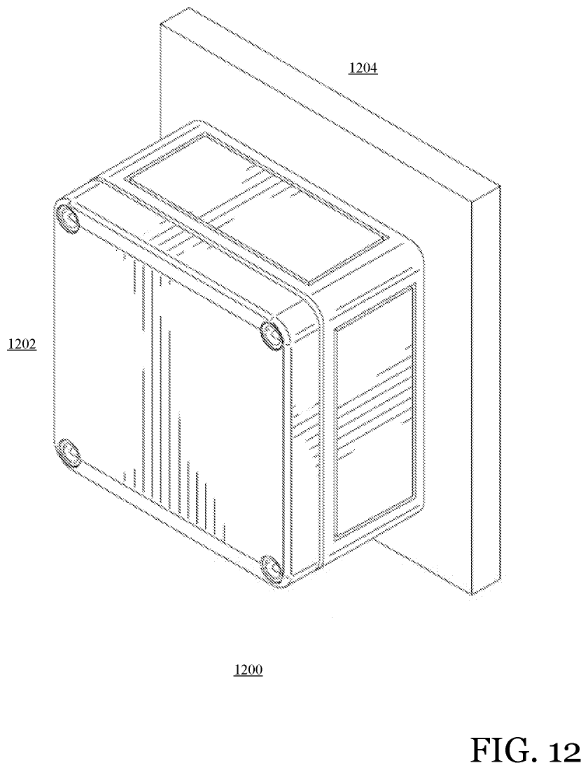

FIG. 12, depicts an example embodiment of a thermal management unit (1200), the equipment housing (1202), and the configuration and mounting to a heat generating component (1204). The inert and durable equipment housing is capable of storage of the PCM, the increased surface area from the conductive matrix disposed to the PCM and in contact with the equipment housing (1202) and or in close proximity or contact with the heat generating component (1204), through the mounting structure, which aids in solving PCM's often low thermal conductivity. The heat generating component may be any number of electrical or mechanical heat flux zones, including cable access nodes, temperature-sensitive units, telecommunication equipment, computing-related equipment, mechanical equipment, electrical equipment, military equipment, or any equipment with a localized heat flux zone. Any size and configuration of equipment housing (1202) may be used to conform to the exterior surface of the heat generating component. The functionality of the PCM material allows it to adapt and conform to variable equipment housing configurations and is deployable across a variety of structures.

The attachment point of the equipment housing (1202) to the heat generating component (1204) may also be sealed with thermal paste or thermal grease. Such application increases the thermal conductivity and further creates a union between the equipment housing (1202) and the heat generating component (1204).

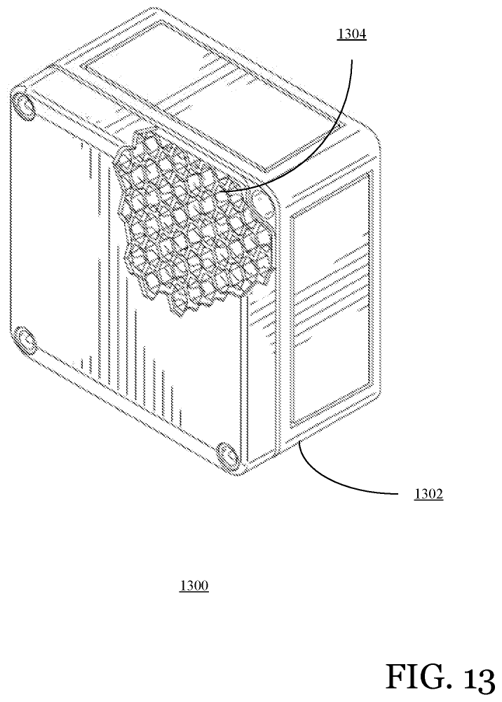

Focusing on FIG. 13, an example embodiment of a thermal management unit with a cut away in the equipment housing displaying a conductive matrix and PCM in liquid phase (1304). The conductive matrix is exemplary of our previous disclosures of honeycomb matrices and metallic foams, with the conductive matrix utilized in increasing the surface area of the heat generating component to the PCM. In our example embodiment of FIG. 13 the liquid state is displayed, however, as discussed previously the phase change may occur to many other combinations or sub combinations, depending upon the PCM selected and the application thereof. The equipment housing (1302) is sealed with gaskets and contains the PCM material and the conductive matrix inside the internal volume. Fasteners, or screws or pins hold the top portion of the equipment housing to the bottom portion of the equipment housing. The bottom portion of the equipment housing is configured with a mounting structure in which the conductive matrix is further configured, thereby bringing the heat transfer properties of the respective elements closer to the PCM.

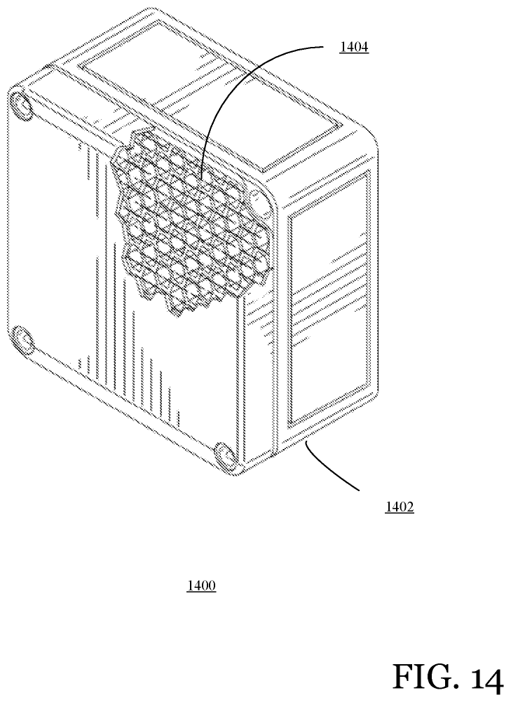

In FIG. 14, an example embodiment of a thermal management unit with a cut away in the equipment housing displaying a conductive matrix and PCM in solid phase (1404) is disclosed. This is but one example embodiment and the solid phase may consist in similar representation of a crystalline phase or mesophase or liquid phase, etc. In the example embodiment the solid phase PCM surrounds and occupies the conductive matrix. The equipment housing (1402) is equipped to handle the physical properties of the respective PCM and is configurable to the given application.

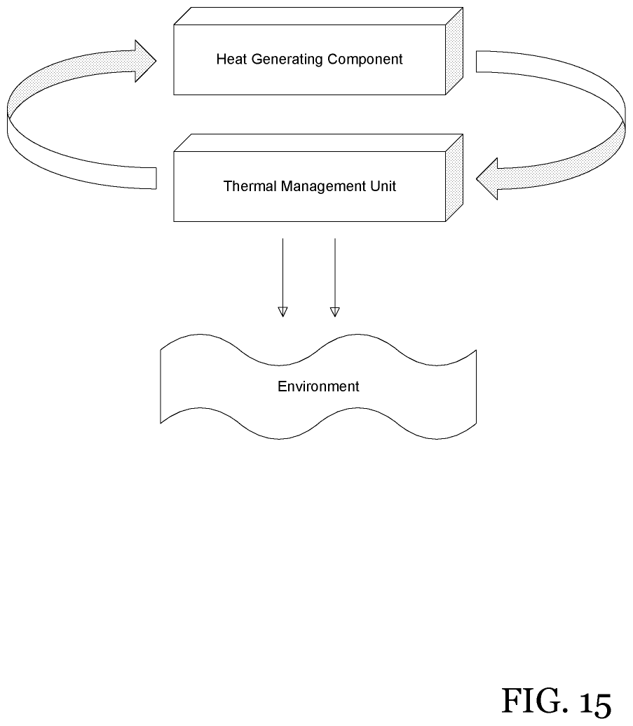

FIG. 15 is a flow chart of an example embodiment of a thermal management unit interacting with a heat generating component in the environment. The heat generating component is often in direct contact with the thermal management unit, via the mounting structure or otherwise the equipment housing is configured to the heat generating component. In additional embodiments the thermal management unit is placed in close proximity to the heat generating component. The thermal management unit interacts with the heat generating component and the environment to provide thermal regulation. In the example embodiment of FIG. 15 the thermal management unit comprises equipment housing with a conductive matrix, and PCM. In additional embodiments the equipment housing may lack a conductive matrix but include PCM. The equipment housing is configurable and capable of being placed in open and closed configurations with various shapes and sizes, as well as compositions, that may prove beneficial with a chosen PCM or apparatus or structure of the heat generating component.

1. A thermal management unit comprising:
a housing having or defining an interior volume;
a thermally conductive matrix disposed in the interior volume of the housing; and
a phase change material (PCM) disposed in the thermally conductive matrix.

2. The thermal management unit of claim 1 further comprising one or more heat-generating components disposed within the interior volume of the housing.

3. The thermal management unit of claim 2, wherein the heat-generating components are in thermal contact with the thermally conductive matrix.

4. The thermal management unit of claim 3, wherein the heat-generating components are in thermal contact with the thermally conductive matrix through a thermal paste or thermal foam disposed between the heat-generating components and the thermally conductive matrix.

5. The thermal management unit of claim 1, wherein the thermally conductive matrix is disposed within a sub-housing.

6. The thermal management unit of claim 5, wherein the sub-housing comprises or is formed from a metal box.

7. The thermal management unit of claim 1, wherein:
the housing has an open configuration and a closed configuration; and
the interior volume of the housing is sequestered from an exterior environment of the housing when the housing is in the closed configuration.

8. The thermal management unit of claim 7, wherein the housing comprises one or more coupling members operable to reversibly place the housing in the open configuration or the closed configuration.

9. The thermal management unit of claim 8, wherein the coupling members comprise one or more screws or pins.

10. The thermal management unit of claim 8, wherein the coupling members comprise one or more hinges.

11. The thermal management unit of claim 1, wherein the housing comprises a top portion (or lid) and a bottom portion (or bottom).

12. The thermal management unit of claim 1, wherein the housing comprises cooling fins on an exterior surface of the housing, opposite the interior volume of the housing.

13. The thermal management unit of claim 1, wherein the thermally conductive matrix comprises or is formed from a metal or mixture or alloy of metals.

14. The thermal management unit of claim 1, wherein the thermally conductive matrix comprises or is formed from silicon carbide (SiC).

15. The thermal management unit of claim 1, wherein the thermally conductive matrix comprises or is formed from a carbon fiber composite.

16. The thermal management unit of claim 1, wherein the thermally conductive matrix comprises or defines a honeycomb structure.

17. The thermal management unit of claim 1, wherein the thermally conductive matrix comprises or defines a foam.

18. The thermal management unit of claim 1, wherein the thermally conductive matrix does not comprise boron nitride (BN) platelets.

19. The thermal management unit of claim 1, wherein the PCM has a phase transition temperature between 45° C. and 85° C.

20. The thermal management unit of claim 1, wherein the PCM has a phase transition temperature between 50° C. and 80° C.

21. A method of managing thermal energy, the method comprising:
placing a heat-generating component in thermal contact with the thermal management unit of claim 1.

22. The method of claim 21, wherein placing the heat-generating component in thermal contact with the thermal management unit comprises disposing the heat-generating component at least partially within the interior volume of the housing of the thermal management unit.

23. The method of claim 21 further comprising one or more of:
conducting thermal energy generated by the heat-generating component from the heat-generating component to the PCM, either directly or through the thermally conductive matrix or through a thermal paste or thermal foam disposed between the heat-generating component and the PCM;
absorbing thermal energy generated by the heat-generating component with the PCM, thereby inducing at least a partial phase transition of the PCM;
releasing thermal energy from the PCM to an external environment of the thermal management unit, the external environment having a lower temperature than the phase transition temperature of the PCM; and
conducting thermal energy from the PCM to the external environment through the housing or a sub-housing of the thermal management unit.
